(19) United States
(12) Patent Application Publication
(10) Pub. No.: US 2021/0072305 A1
(43) Pub. Date: Mar. 11, 2021

(54) ONLINE TEST DATA RECORD AND OFFLINE DATA CONVERSION ANALYSIS SYSTEM, AND METHOD

(71) Applicants: Inventec (Pudong) Technology Corporation, Shanghai (CN); INVENTEC CORPORATION, Taipei (TW)

(72) Inventor: Yong-Jun SHI, Shanghai (CN)

(73) Assignees: Inventec (Pudong) Technology Corporation, Shanghai (CN); INVENTEC CORPORATION, Taipei (TW)

(21) Appl. No.: 17/013,675

(22) Filed: Sep. 7, 2020

(30) Foreign Application Priority Data
Sep. 9, 2019 (CN) 2019108576144

(51) Int. Cl. G01R 31/28; G06F 11/263

(52) U.S. Cl. CPC G01R 31/2815; G06F 11/2635; G01R 31/2853; G01R 31/2803

(57) ABSTRACT

The disclosure provides an online test data record and offline data conversion analysis system and a method thereof. In the present disclosure, the test process information of the production line testing system performed on the circuit board to be tested is generated into online test result data in a database file format, and the offline analysis system receives the online test data from the production line testing system. The offline analysis system reads the corresponding data in the online test result data according to the designated data in the data designated instruction, and generates the offline test result data in the designated file format of the data designated instruction, and the offline analysis system perform the data analysis for the offline test result according to the analysis instruction.

### CROSS REFERENCES TO RELATED APPLICATIONS

This application claims the benefit of priority to Chinese Patent Application No. CN 201910857614.4, entitled “Online Test Data Record and Offline Data Conversion Analysis System, and Method”, filed with CNIPO on Sep. 9, 2019, the contents of which are incorporated herein by reference in its entirety.

### TECHNICAL FIELD

The present disclosure provides a recording and conversion analysis system and method thereof, and in particular, to an online test data record and offline data conversion analysis system, and method.

### BACKGROUND

In the production line, in order to ensure the quality of the circuit board, the boundary scan test is usually performed on the circuit board in the production line. The boundary scan test is performed to find the defects on pins of the electronic components on the circuit board, such as open circuit, short circuit, etc., for quick troubleshooting and problem solving.

In the existing line boundary scan test system, the test results during the test process and after the test are displayed in the graphical user interface, rather than recording the test data in the files. Or only a small number of result data is recorded in the files. Meanwhile, the test data is not summarized or counted. With the increasing number of circuit board producing and testing on production line, the traditional method which does not record the data or only records in text files fails to meet actual requirements.

It is urgent to solve the problem that test data of circuit board on the existing production line is not recorded.

### SUMMARY

The present disclosure provides an online test data record and offline data conversion analysis system and methods thereof.

The online test data recording and offline data conversion analysis system disclosed includes: an offline analysis system and a production line testing system, and the offline analysis system further comprises: an offline receiving module, a data generation module, a storage module and data analysis module; the production line testing system further comprises: a receiving module, a querying module, a parsing module, a testing module, a recording module, and a transmission module.

The offline receiving module of the offline analysis system is used for receiving the online test result data, receiving the data designated instruction, and receiving the analysis instruction; the offline analysis system data generation module is used for reading the online test according to the designated data in the data designated instruction, and generates the corresponding data in the result data and the offline test result data are generated by the file format designated in the data designated instruction; the storage module of the offline analysis system is used to store the offline test result data; and the data analysis module of the offline analysis system is used to performs data analysis on the offline test result data according to the analysis instruction when the offline receiving module receives the analysis command.

The receiving module of the production line testing system is used for receiving the test script name of the circuit board to be tested; the query module of the production line testing system is used for querying the test script according to the test script name; the analysis module of the production line testing system is at least one test item for parsing the test script; the testing module of the production line testing system is used for performing the corresponding test on the circuit board to be tested according to at least one test item of the test script; the record module of the production line testing system uses the information for testing the testing module on the test board to generate online test result data in a database file format; and the transmission module of the production line testing system is used to transmit the online test result data to the offline receiving module.

The online test data recording and offline data conversion analysis method disclosed by the present disclosure comprises the following steps:

Firstly, the production line testing system receives the test script name of the circuit board to be tested; then, the production line testing system queries the test script according to the test script name; then, the production line testing system parses at least one test item of the test script; then, the line testing system performs corresponding tests on the circuit board to be tested according to at least one test item of the test script; and then, the line testing system generate the online test result data in the database file format based on a test process information of the circuit board to be tested; then, the offline analysis system receives the online test result data from the production line testing system; then, the offline analysis system receives the data designated instruction; then, the offline analysis system reads the corresponding data in the online test result data according to the specified data in the data designated instruction and generates the offline test result data in the file format designated in the data designated instruction; then, the offline analysis system stores offline test result data; finally, when the analysis system offline receives the analysis instruction, the off-line test data is analyzed according to the analysis instruction.

In the present disclosure, the test process information of the production line testing system performed on the circuit board to be tested is generated into online test result data in a database file format, and the offline analysis system receives the online test data from the production line testing system. The offline analysis system reads the corresponding data in the online test result data according to the designated data in the data designated instruction, and generates the offline test result data in the designated file format of the data designated instruction, and the offline analysis system perform the data analysis for the offline test result according to the analysis instruction.

This present disclosure can solve the problem of no data record for circuit board tests in the prior art, and record the online test data, and provide offline data conversion and analysis.

### BRIEF DESCRIPTION OF THE DRAWINGS

FIG. 1 is a schematic diagram of an online test data recording and an offline data conversion analysis system of the present disclosure.

FIGS. 2A to 2C are schematic diagrams of partial online test result data of the online test data record and offline data conversion analysis of the present disclosure.

FIG. 3A is a schematic diagram of offline test result data stored in a plain text file format for online test data recording and offline data conversion analysis according to the present disclosure.

FIG. 3B is a schematic diagram of offline test result data stored in a normal text file format for online test data recording and offline data conversion analysis according to the present disclosure.

FIG. 3C is a schematic diagram of offline test result data stored in a Java Script object representation file format for online test data recording and offline data conversion analysis according to the present disclosure.

FIG. 4A and FIG. 4B are flowcharts of a method for recording online test data and conversing and analyzing offline data according to the present disclosure.

### DESCRIPTION OF REFERENCE NUMERALS

10 offline analysis system
11 offline receiving module
12 data generation module
13 storage module
14 data analysis module
20 production line testing system
21 receiving module
22 query module
23 parsing module
24 testing module
25 recording module
26 transmission module
31 data
32 data
33 pin data
34 test results
41 offline test result data
   Step 101: The production line testing system receives the test script name of the board to be tested.
   Step 102: The production line testing system queries the test script according to the test script name.
   Step 103: The production line testing system parses at least one test item of the test script.
   Step 104: The production line testing system performs corresponding tests on the circuit board to be tested according to at least one test item of the test script.
   Step 105: The production line testing system generates the online test result data in the database file format based on the testing process of the circuit board to be tested.
   Step 106: The offline analysis system receives online test result data from the production line testing system.
   Step 107: The offline analysis system receives data designated instructions.
   Step 108: The offline analysis system reads the corresponding data in the online test result data according to the designated data in the data designated instruction and generates the offline test result data in the file format designated in the data designated instruction.
   Step 109: The offline analysis system stores offline test result data.
   Step 110: When the offline analysis system receives the analysis instruction, the offline test result data is analyzed according to the analysis instructions.

### DETAILED DESCRIPTION OF THE PREFERRED EMBODIMENTS

The embodiments of the present disclosure will be described in detail below with reference to the drawings and embodiments, so that the application of the technical means to solve the technical problems and the implementation of the technical effects can be fully understood and implemented.

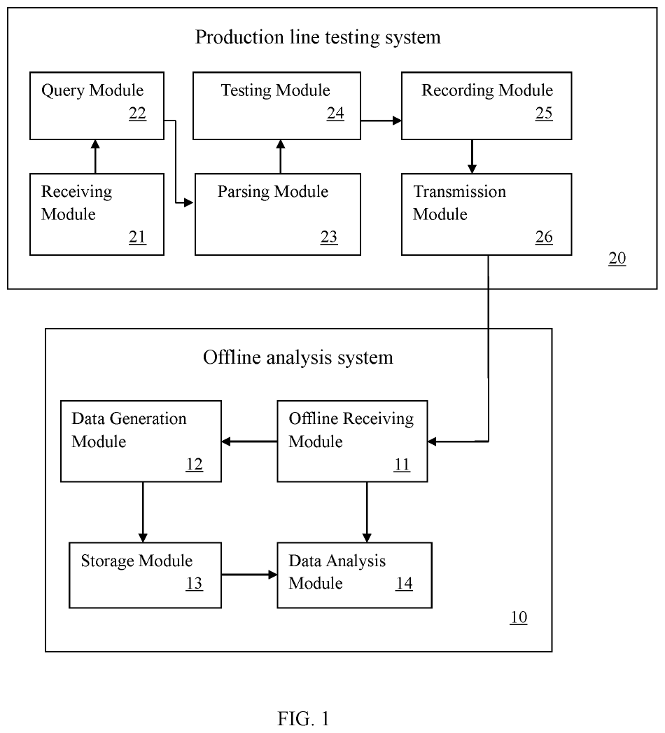

The following describes the online test data record and the offline data conversion analysis system in the present disclosure first. FIG. 1 is a schematic diagram of the online test data record and the offline data conversion analysis system according to the present disclosure.

The online test data recording and offline data conversion analysis system includes: an offline analysis system 10 and a production line testing system 20. The offline analysis system 10 further includes: an offline receiving module 11, a data generation module 12, a storage module 13, and a data analysis module 14. The production line testing system 20 further includes a receiving module 21, a query module 22, a parsing module 23, a testing module 24, a recording module 25, and a transmission module 26.

When testing the circuit board on the production line, the operator can select the test script name for the circuit board to be tested through the user interface provided by the production line testing system 20, the receiving module 21 of the production line testing system 20 receives the test script name of the circuit board to be tested.

When the receiving module 21 of the production line testing system 20 receives the test script name of the circuit board to be tested, the query module 22 of the production line testing system 20 queries the test script according to the test script name. It should be noted that the test script is a boundary scan test script.

After the query module 22 of the production line testing system 20 queries the test script, the parsing module 23 of the production line testing system 20 parses out at least one test item of the test script, and the test item includes an integrity test, ground (GND) test, power test, pull-up test, pull-down test, and connection test.

Specifically, the parsing module 23 of the production line testing system 20 can parse that the test item of the test script is an integrity test. The parsing module 23 of the production line testing system 20 can parse that the test item of the test script is a ground test. The parsing module 23 of the line testing system 20 can parse that the test item of the test script is integrity test, power supply test, and connection test. The parsing results are module 23 of the production line testing system 20 can parse that the test item of the are merely examples, and are not intended to limit the scope of application of the present disclosure.

Then, the testing module 24 of the production line testing system 20 can perform corresponding tests on the circuit board to be tested according to at least one test item of the test script through the boundary scan technology. Specifically, if the parsing module 23 of the production line testing system 20 parses that the test item of the test script is an integrity test, the testing module 24 of the production line testing system 20 will perform the integrity test on the circuit board to be tested. If the parsing module 23 of the production line testing system 20 parses that the test items of the test script are GND test, power supply test and connection test, the testing module 24 of the production line testing system 20 will perform GND test, power supply test and connection test on the circuit board to be tested. The exemplary examples do not limit the scope of the present disclosure.

Then, the recording module 25 of the production line testing system 20 records the information in the test process (at the beginning of the testing, in the middle of testing, and after the test) tested by the testing module 24 of the production line testing system 20, and generates online test result data in a database file format.

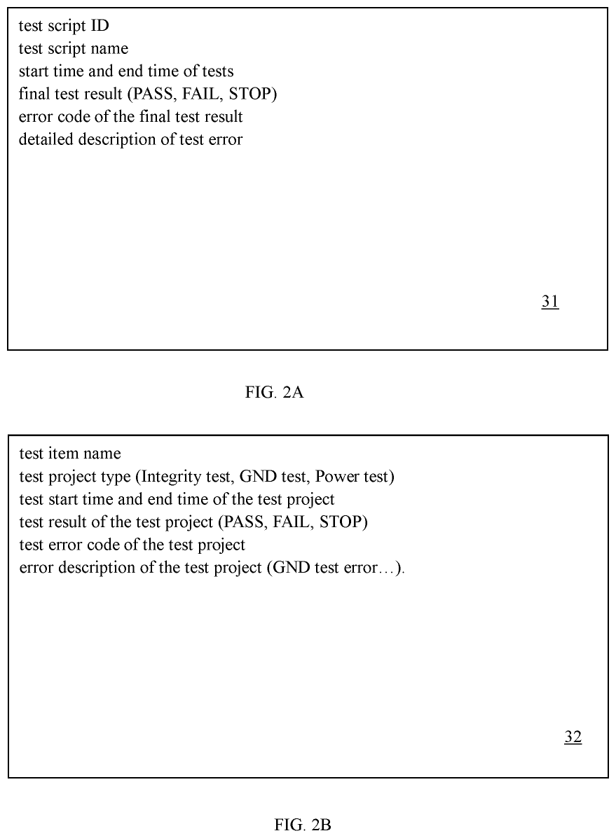

Please referring to FIG. 2A, FIG. 2A is a schematic diagram of partial online record and offline data conversion analysis of the present disclosure.

The recording module 25 of the production line testing system 20 records the data 31 of the test script when the circuit board to be tested is started for testing. The data 31 of the test script is a part of the online test result data, and the data 31 of the test script includes test script ID, test script name, test start time and end time, final test result, error code of the last test result, and detailed descriptions of test error.

Please referring to FIG. 2B, FIG. 2B is a schematic diagram of partial online test result data of the online test data record and offline data conversion analysis of the present disclosure.

The recording module 25 of the production line testing system 20 records the test data 32 when the circuit board to be tested is being tested. The test data 32 is part of the online test result data, and the test data 32 includes the test item name, the test project type, the start time and end time of the test project test, the test result of the test project, the test error code of the test project, and the description of the test error.

Please refer to FIG. 2C, FIG. 2C is a schematic diagram of partial online test result data of the online test data record and offline data conversion analysis of the present disclosure.

The recording module 25 of the production line testing system 20 records the pin data 33 of the tested components in the circuit board to be tested, the test result 34 of the component type, and the test result of the test script after the end of the test. Each pin data 33 of the tested component in the circuit board includes a pin name, a net name, a test result, and detailed description information. The component type test result 34 includes the component type and the test result, and the test results of the test script are as above-mentioned.

The production line testing system 20 and the offline analysis system 10 are connected with each other by wire transmission or wireless transmission. The wire transmission includes a cable network, a fiber network, etc. The wireless transmission includes Wi-Fi, mobile communication network (3G, 4G, 5G) etc. The examples do not limit the scope of the present disclosure.

After the recording module 25 of the production line testing system 20 generates the online test result data in the database file format, the online test result data can be transmitted through the transmission module 26 of the production line testing system 20 to offline receiving module 11 of the offline analysis system 10. The offline analysis system 10 stores the online test result data.

When the test result data needs to be analyzed, the offline receiving module 11 of the offline analysis system 10 receives the data designated instruction, and the offline receiving module 11 of the offline analysis system 10 receives the analysis instruction.

The data generation module 12 of the offline analysis system 10 can read the corresponding data in the online test result data according to the designated data in the data designated instruction, and generates the offline test result data in the file format specified in the data designated instruction, and the storage module 13 of the offline analysis system 10 stores offline test result data. The designated file format includes a plain text file format (txt file format), a Java Script object representing file format (json file format), and a normal text file format (err file format), etc. The exemplary file formats do not limit the scope of the disclosure.

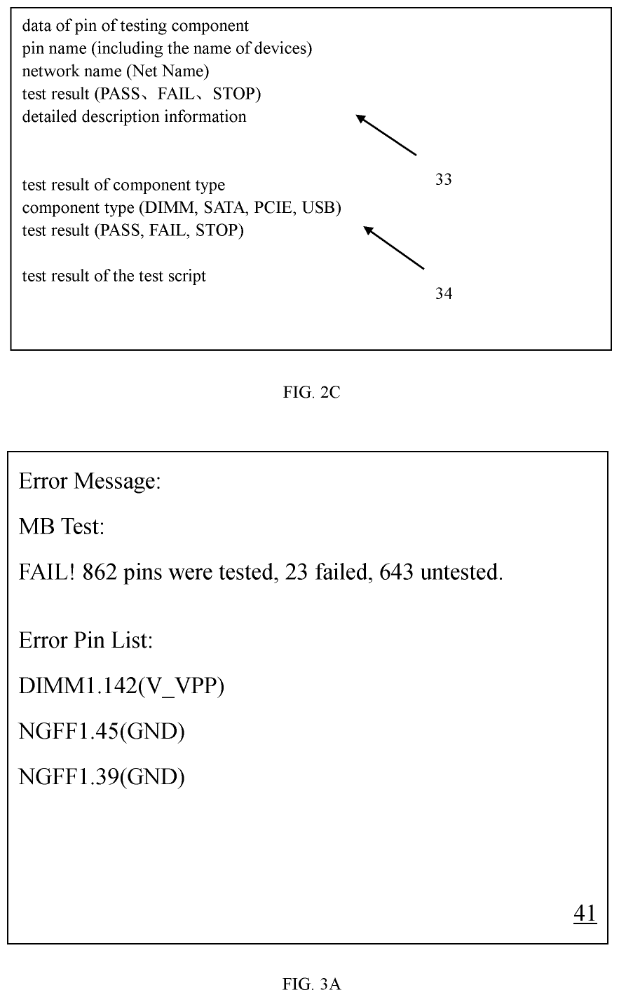

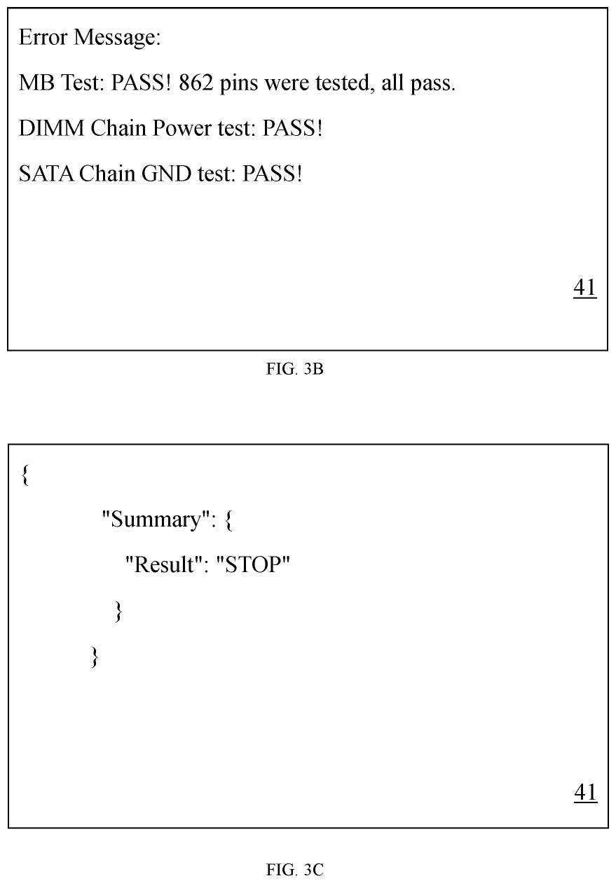

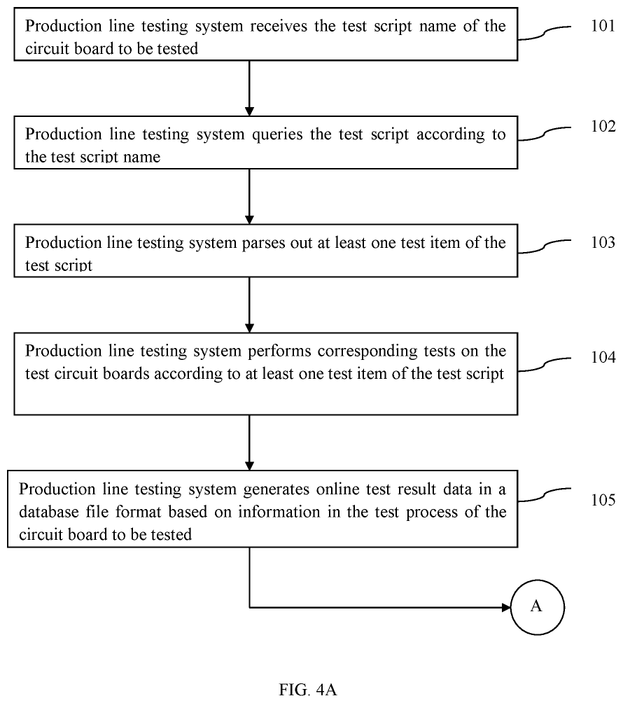

Please referring to FIG. 3A. FIG. 3A is a schematic diagram of offline test result data stored in a plain text file format for online test data recording and offline data conversion analysis according to the present disclosure.

For the content of the offline test result data 41 stored in the plain text file format, please referring to FIG. 3A, and the details are not repeated herein. The offline test result data 41 includes an error message and a list of error pins. The error information includes the script name and the script test result. The list of error pins includes error pin name, and the network name. The exemplary examples do not limit the scope of the disclosure.

Please referring to FIG. 3B, FIG. 3B is a schematic diagram of offline test result data stored in a normal text file format for online test data recording and offline data conversion analysis according to the present disclosure.

The content of the offline test result data 41 stored in the normal text file format is shown in FIG. 3B, and is not repeated here. The offline test result data 41 includes error information and a test item list, and the error information includes the script name and the script test result. The exemplary examples are merely illustrative here, and are not intended to limit the scope of the present disclosure.

Please referring to FIG. 3C. FIG. 3C is a schematic diagram of offline test result data stored in a Java Script object representation file format for online test data recording and offline data conversion analysis according to the present disclosure.

Please referring to FIG. 3C for the content of the offline test result data 41 stored in the file format of the Java Script object, the details are not repeated herein. The offline test result data 41 includes the script test result, the script test error code, the component type, and the component pin name, the component pin test error description, and the network name. The exemplary examples are merely illustrative here, and are not intended to limit the scope of the present disclosure.

When the offline receiving module 11 of the offline analysis system 10 receives the analysis instruction, the data analysis module 14 of the offline analysis system 10 performs data analysis on the offline test result data according to the analysis instruction, thereby providing results in different file formats and can be offline data analyzed.

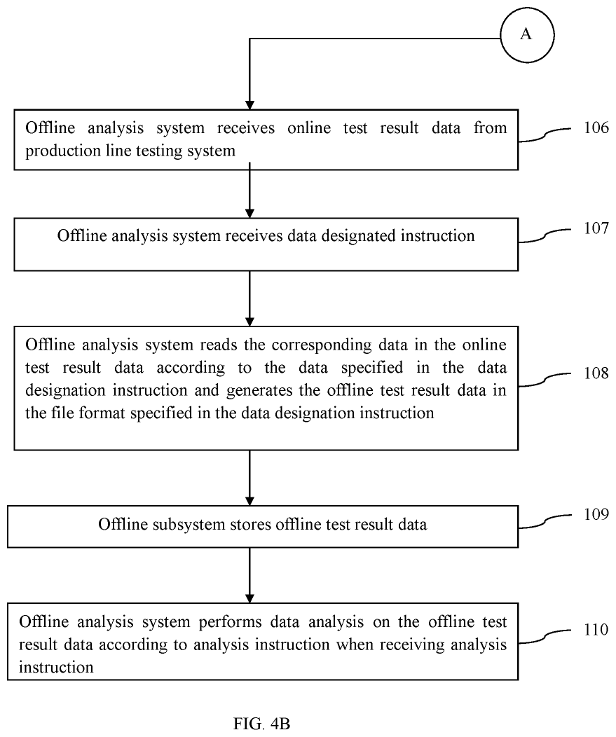

Please referring to FIG. 4A and FIG. 4B. FIG. 4A and FIG. 4B are flowcharts of a method for recording online test data and conversing and analyzing offline data according to the present disclosure.

Firstly, the production line testing system receives the test script name of the circuit board to be tested (step 101); then, the production line testing system queries the test script according to the test script name (step 102); then, the production line testing system parses at least one test item of the test script (step 103); then, the line testing system performs corresponding tests on the circuit board to be tested according to at least one test item of the test script (step 104); and then, the line testing system generate the online test result data in the database file format based on a test process information of the circuit board to be tested (step 105); then, the offline analysis system receives the online test result data from the production line testing system (step 106); then, the offline analysis system receives the data designated instruction (step 107); then, the offline analysis system reads the corresponding data in the online test result data according to the specified data in the data designated instruction and generates the offline test result data in the file format designated in the data designated instruction (step 108); then, the offline analysis system stores offline test result data (step 109); finally, when the analysis system offline receives the analysis instruction, the off-line test data is analyzed according to the analysis instruction (step 110).

In summary, in the present disclosure, the test process information of the production line testing system performed on the circuit board to be tested is generated into online test result data in a database file format, and the offline analysis system receives the online test data from the production line testing system. The offline analysis system reads the corresponding data in the online test result data according to the designated data in the data designated instruction, and generates the offline test result data in the designated file format of the data designated instruction, and the offline analysis system perform the data analysis for the offline test result according to the analysis instruction.

This present disclosure can solve the problem of no data record for circuit board tests in the prior art, and record the online test data, and provide offline data conversion and analysis.

Although the disclosed embodiments of the present disclosure are as described above, the contents are not intended to directly limit the scope of the present disclosure. Any changes in the form and details of the embodiments may be made without departing from the spirit and scope of the disclosure. The scope of the present disclosure is determined by the scope of the appended claims.

1. An online test data record and offline data conversion analysis system, comprising:
an offline analysis system, and
a production line testing system;
wherein the offline analysis system comprises:
an offline receiving module, receiving online test result data, receiving data designated instruction, and receiving analysis instruction;
a data generation module, reading corresponding data in the online test result data according to the designated data of the data designated instruction and generating offline test result data according to the designated file format of the data designated instruction;
a storage module, storing the offline test result data; and
a data analysis module, performing data analysis on the offline test result data according to the analysis instruction when the offline receiving module receives the analysis instruction;
wherein production line testing system comprises:
a receiving module, receiving a test script name of the circuit board to be tested;
a query module, querying a test script according to the test script name;
a parsing module, parsing at least one test item of the test script;
a testing module, performing the corresponding test on the circuit board to be tested according to the at least one test item of the test script;
a recording module, generating the online test result data in a database file format by using the testing module based on testing process information of the circuit board to be tested; and
a transmission module, transmitting the online test result data to the offline receiving module.

2. The online test data recording and offline data conversion analysis system according to claim 1, wherein the test item comprises an integrity test, a ground test, a power test, a pull-up test, a pull-down test, connection test.

3. The online test data record and offline data conversion analysis system according to claim 1, wherein the designated file format comprises a plain text file format, a JavaScript object representing file format, and a normal text file format.

4. The online test data recording and offline data conversion analysis system according to claim 1, wherein the recording module records data of the test script when testing on the circuit board to be tested begins; the recording module records the test data during the testing; and the recording module records the data of each pin of the tested component, the test result of the component type, and the test result of the test script when the testing on the circuit board to be tested is completed.

5. The online test data recording and offline data conversion analysis system according to claim 1, wherein the testing module tests the circuit boards to be tested respectively by the boundary scan technology according to at least one test item of the test script, and the test script is a boundary scan test script.

6. An online test data record and offline data conversion analysis method, comprising the following steps:
receiving, by a production line testing system, the test script name of the circuit board to be tested;
querying, by a production line testing system, the test script according to the test script name;
parsing, by the production line testing system, at least one test item of the test script;
performing, by the production line testing system, the corresponding tests on the circuit board to be tested according to the at least one test item of the test script;
generating, by the production line testing system, online test result data in a database file format by using the information of the test process of the circuit board to be tested;
receiving, by an offline analysis system, the online test result data from the production line testing system;
receiving, by the offline analysis system, a data designated instruction;
reading, by the offline analysis system, the corresponding data in the online test result data according to the designated data of the data designated instruction, and generating offline test result data in a designated file format of the data designated instruction;
storing, by the offline analysis system, the offline test result data; and
performing data analysis on the offline test result data according to the analysis instruction when the offline analysis system receives the analysis instruction.

7. The method for the online test data recording and offline data conversion analysis according to claim 6, wherein the test item comprises an integrity test, a ground test, a power test, a pull-up test, a pull-down test, a connection test.

8. The method for the online test data record and offline data conversion analysis according to claim 6, wherein the designated file format comprises a plain text file format, a Java Script object representing file format, and a normal text file format.

9. The method for the online test data recording and offline data conversion analysis method according to claim 6, wherein the generating, by the production line testing system, online test result data in a database file format by using the information of the test process of the circuit board to be tested further comprises:
recording, by the production line testing system, data of the test script, when the production line testing system begins testing on the circuit board to be tested;
recording, by the production line testing system, the test data during testing; and
recording, by the production line testing system, the data of each pin of the tested component in the circuit board to be tested, the test result of the component type and the test result of the test script, when the test on the circuit board to be tested is completed.

10. The method for the online test data recording and offline data conversion analysis method according to claim 6, wherein the production line testing system tests the circuit boards to be tested respectively by the boundary scan technology according to at least one test item of the test script, and the test script is a boundary scan test script.
